(19) United States
(12) Patent Application Publication
(10) Pub. No.: US 2007/0267757 A1
(43) Pub. Date: Nov. 22, 2007

(54) Semiconductor device

(75) Inventor: Masaki Nakagawa, Fukuoka (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/798,938

(22) Filed: May 17, 2007

(30) Foreign Application Priority Data
May 18, 2006 (JP) 2006-139622

(51) Int. Cl. H01L 23/48

(52) U.S. Cl. 257/778

(57) ABSTRACT

A semiconductor device of the present invention includes a semiconductor chip provided with a plurality of electrodes on one surface thereof in the thickness direction and a resin layer provided so as to overlap the one surface of the semiconductor chip. In the semiconductor device, a surface of the resin layer is used as a mounting surface, and the semiconductor device is mounted on a mounting substrate with an underfill material filled between the mounting surface and the mounting substrate. In the mounting surface, grooves which divide the mounting surface into a plurality of surfaces are provided.

### BACKGROUND OF THE INVENTION

1. Field of the Invention

The present invention relates to a semiconductor device, and particularly to a semiconductor device called a wafer level CSP (Chip Scale (or Size) Package).

2. Description of Related Art

As one form of a semiconductor device, there is one called a wafer level CSP or wireless CSP.

The wafer level CSP is composed of a semiconductor chip provided with a plurality of electrodes on one surface thereof in a thickness direction, and a resin layer provided in an overlapping manner on the electrode arranged surface side of the semiconductor chip. This wafer level CSP is directly mounted on a mounting substrate without being contained in a conventional container called a package.

In the resin layer, copper-made posts are embedded, and rewiring which electrically connects the posts to the electrodes of the semiconductor chip are embedded. Solder terminals are fitted to the posts, and the posts are electrically connected via the solder terminals to terminals provided in the mounting substrate.

The gap between the resin layer and the mounting substrate is filled with an underfill material. Due to this underfill material, the solder terminals are sealed and the wafer level CSP is firmly mounted on the mounting substrate.

However, as shown in FIG. 8, in some cases, a stress F caused by contraction of the underfill material 300 when it cures is applied to the resin layer 200 in contact with the underfill material 300, the resin layer 200 separates from the semiconductor chip 100, and disconnection occurs between the semiconductor chip 100 and the resin layer 200 or the semiconductor chip 100 itself is broken. In FIG. 8, the reference numeral 400 denotes the semiconductor terminal, and 500 denotes the mounting substrate.

### SUMMARY OF THE INVENTION

A semiconductor device of the present invention includes a semiconductor chip provided with a plurality of electrodes on one surface thereof in the thickness direction, and a resin layer provided in an overlapping manner on the one surface of the semiconductor chip. This semiconductor device is mounted on the mounting substrate with an underfill material filled between the mounting surface and the mounting substrate by using the surface of the resin layer as the mounting surface. In the mounting surface, a groove which divide the mounting surface into a plurality of surfaces are provided.

Since the grooves are provided in the mounting surface of the resin layer, the grooves can reduce stress applied to the resin layer caused according to curing of the underfill material. Therefore, the resin layer can be prevented from separating from the semiconductor chip. As a result, disconnection between the semiconductor chip and the resin layer and breakage of the semiconductor chip itself can be prevented.

In the resin layer, a plurality of metal posts to which solder terminals are respectively connected are provided, and it is preferable that the groove is provided along outer edges of the resin layer between the outer edges and the posts. In this case, even if the resin layer separates from the semiconductor chip due to a stress applied to the resin layer according to curing of the underfill material, the separation can be suppressed from spreading over the groove. Therefore, the functional parts of the semiconductor chip can be prevented from being damaged. In addition, since the underfill material enters the groove, the contact area between the resin layer and the underfill material increases, and the entering underfill material functions as an anchor, whereby the adhesion between the underfill material and the resin layer can be improved.

When the mounting surface is in a rectangular shape, the grooves may be provided along four respective outer peripheral edges of the mounting surface, or may be provided along two outer peripheral edges adjacent to each other among the four outer peripheral edges of the mounting surface. In the latter case, while the number of grooves is minimized to minimize the burden of the groove formation, disconnection between the semiconductor chip and the resin layer and breakage of the semiconductor chip itself can be prevented.

The grooves may be inclined at a predetermined angle with respect to the mounting surface. In this case, the stress applied to the resin layer according to curing of the underfill material can be more satisfactorily reduced. Therefore, separation of the resin layer from the semiconductor chip can be reliably prevented. As a result, disconnection between the semiconductor chip and the resin layer and breakage of the semiconductor chip itself can be reliably prevented.

The groove may have a step formed by a portion grooved relatively shallowly and a portion grooved relatively deeply. In this case, the stress applied to the resin layer according to curing of the underfill material can be more satisfactorily reduced. Therefore, separation of the resin layer from the semiconductor chip can be reliably prevented. As a result, disconnection between the semiconductor chip and the resin layer and breakage of the semiconductor chip itself can be reliably prevented.

The above-described and other objects, features, and effects of the present invention will be made clear from the following description of embodiments with reference to the accompanying drawings.

### BRIEF DESCRIPTION OF THE DRAWINGS

FIG. 1(A) is a bottom view of a semiconductor device according to an embodiment of the present invention, and FIG. 1(B) is a sectional view along the X-X line of FIG. 1(A);

FIG. 2 is a bottom view of a semiconductor device according to another embodiment;

FIG. 3 is a sectional view showing a first modification example of a groove shape;

FIG. 4 is a sectional view showing a second modification example of the groove shape;

FIG. 5 is a sectional view showing a third modification example of the groove shape;

FIG. 6 is a sectional view showing a fourth modification example of the groove shape;

FIG. 7 is a sectional view showing a fifth modification example of the groove shape; and

FIG. 8 is a sectional view for describing separation of a resin layer occurring in a conventional semiconductor device.

### DETAILED DESCRIPTION OF PREFERRED EMBODIMENTS

Hereinafter, embodiments of the present invention will be described in detail with reference to the drawings.

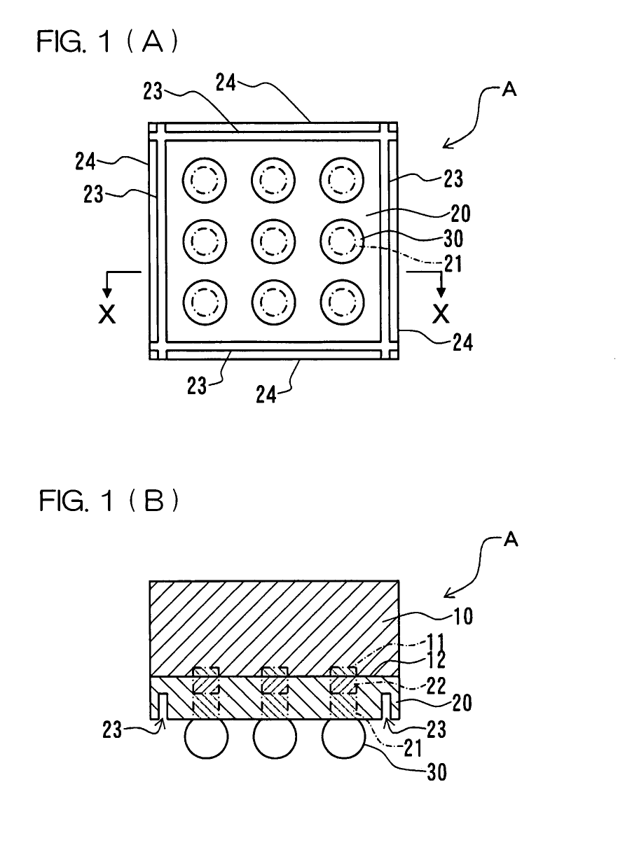

FIG. 1(A) is a bottom view of a semiconductor device according to an embodiment of the present invention. FIG. 1(B) is a sectional view along the section line X-X of the semiconductor device of FIG. 1(A).

The semiconductor device A of this embodiment is composed of a semiconductor chip 10 provided with a plurality of electrodes 11 arranged on one surface 12 in the thickness direction, and a resin layer 20 provided so as to overlap the electrode arranged surface 12 provided with the electrodes 11.

In the resin layer 20, copper-made posts 21 are embedded. In addition, in the resin layer 20, rewiring 22 made of copper wiring for electrically connecting the posts 21 with the electrodes 11 of the semiconductor chip 10 is embedded. On the surface of the resin layer 20, solder terminals 30 formed of solder balls connected to the respective posts 21 are arranged.

The surface of the resin layer 20 is a mounting surface for mounting the semiconductor device A on a mounting substrate. In this mounting surface, grooves 23 which divide the mounting surface into a plurality of surfaces are formed. In FIG. 1, the grooves 23 divide the mounting surface of the resin layer 20 into nine surfaces. Herein, the mounting substrate means not only a general mounting substrate formed of a glass epoxy substrate but also a package used for hermetically sealing the semiconductor device A.

By thus providing the grooves 23 in the mounting surface of the resin layer 20, when a stress is applied to the resin layer according to curing of the underfill material, the stress can be dispersed and reduced by the grooves 23, so that the resin layer 20 can be prevented from separating from the semiconductor chip 10. Therefore, disconnection between the semiconductor chip 10 and the resin layer 20 due to separation of the resin layer 20 from the semiconductor chip 10 or breakage of the semiconductor chip 10 itself due to the separation can be prevented.

It is desirable that, as shown in FIG. 1(A), the grooves 23 are provided along the outer edges 24 of the resin layer 20 in a rectangular shape in a plan view between the outer edges 24 and the posts 21.

By thus providing the grooves 23 as close as possible to the outer edges 24, at the outer edge 24 portions of the resin layer 20 to which the greatest stress is applied according to curing of the underfill material, the stress can be reduced. In addition, even if the resin layer 20 separates from the semiconductor chip 10 due to the stress applied to the resin layer 20, the resin layer 20 becomes thin and easy to bend at the groove 23 portions, so that the stress can be greatly reduced at the groove 23 portions. Therefore, spreading of the separation of the resin layer 20 into the inner side over the grooves 23 can be suppressed. As a result, disconnection between the electrodes 11 of the semiconductor chip 10 and the rewiring 22 of the resin layer 20 (damage to functional parts) can be prevented.

In addition, since the underfill material enters the grooves 23, the contact area between the resin layer 20 and the underfill material increases, and the underfill material entering the groove 23 portions functions as an anchor, whereby the adhesion between the underfill material and the resin layer 20 can be improved.

The grooves 23 can be formed while the grooving depths are adjusted by using a dicing machine which is used for cutting and separating semiconductor chips from a wafer in a semiconductor chip production process.

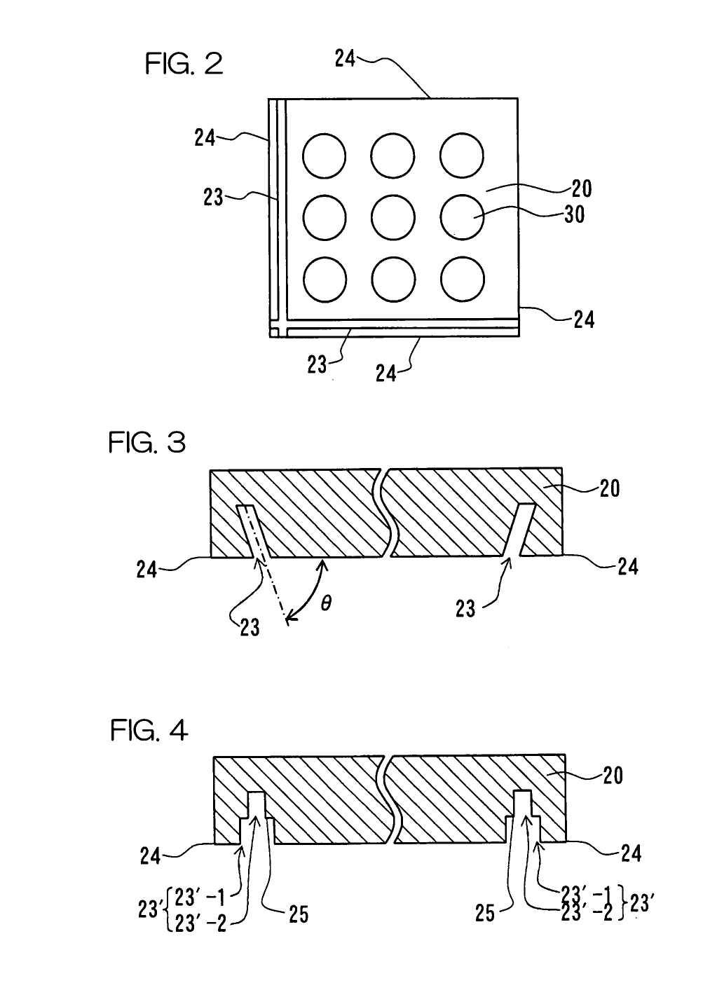

The grooves 23 may be provided on the four outer edges 24 of the resin layer 20 in a rectangular shape in a plan view, as shown in FIG. 1(A), or may be provided on two outer peripheral edges 24 adjacent to each other among the four outer peripheral edges 24, as shown in FIG. 2. In other words, the grooves 23 may be provided along two outer peripheral edges 24 forming one corner among the four outer peripheral edges 24.

Normally, after the semiconductor device A is mounted on a mounting substrate, an underfill material is applied with a dispenser along two outer peripheral edges adjacent to each other of the semiconductor device A, and by using the surface tension, that is, the capillary phenomenon, of the underfill material, the underfill material is wet-spread between the resin layer 20 and the mounting substrate. This underfill material cures while contracting so as to be drawn to the underfill material applied portion side. At the underfill material applied portion, a sufficient amount of underfill material is present, so that a great stress does not occur when the underfill material cures. However, to the tip end of the underfill material wet-spread portion, due to a small amount of the underfill material, the greatest stress is applied.

Therefore, by providing the grooves 23 along the two outer peripheral edges 24 of the resin layer 20 which become tip end sides of the wet-spreading and are adjacent to each other, the stress applied when the underfill material cures can be most effectively reduced. In addition, in comparison with the construction shown in FIG. 1(A), the amount of formation of the grooves 23 can be reduced by half, so that the time taken for forming the grooves 23 can be shortened by half, and the manufacturing efficiency can be improved.

The grooves 23 may also be formed by laser cutting without using a dicing machine.

Particularly, when the grooves 23 are formed in the resin layer 20 by laser cutting, as shown in FIG. 3, they may be inclined at a predetermined angle θ with respect to the mounting surface of the resin layer 20. By thus forming the grooves inclined with respect to the mounting surface of the resin layer 20, the outer peripheral edges 24 of the resin layer 20 can be made easy to bend. As a result, the stress reducing function can be improved.

In this embodiment, the grooves 23 are inclined toward the center side of the resin layer 20. However, they may be inclined toward the outside of the resin layer 20. In this case, a portion of the resin layer 20 inward of the grooves 23 can be made easy to bend. As a result, the stress reducing function can be improved.

As another embodiment, as shown in FIG. 4, grooves 23′ each provided with a step 25 so as to change in depth along the width direction may be formed in the resin layer 20. Particularly, in the embodiment shown in FIG. 4, a first groove 23′-1 with a predetermined width is formed first by using a diamond cutter that is used for dicing, and then a second groove 23′-2 with a width smaller than that of the first groove 23′-1 is formed at the center of the first groove 23′-1, whereby the step 25 is formed.

When thus providing the step 25, it becomes easy to fill the inside of the groove 23′ with the underfill material, and the adhesion between the underfill material and the resin layer 20 can be improved. In addition, it can be made easy to prevent the mixing of air when the underfill material is filled.

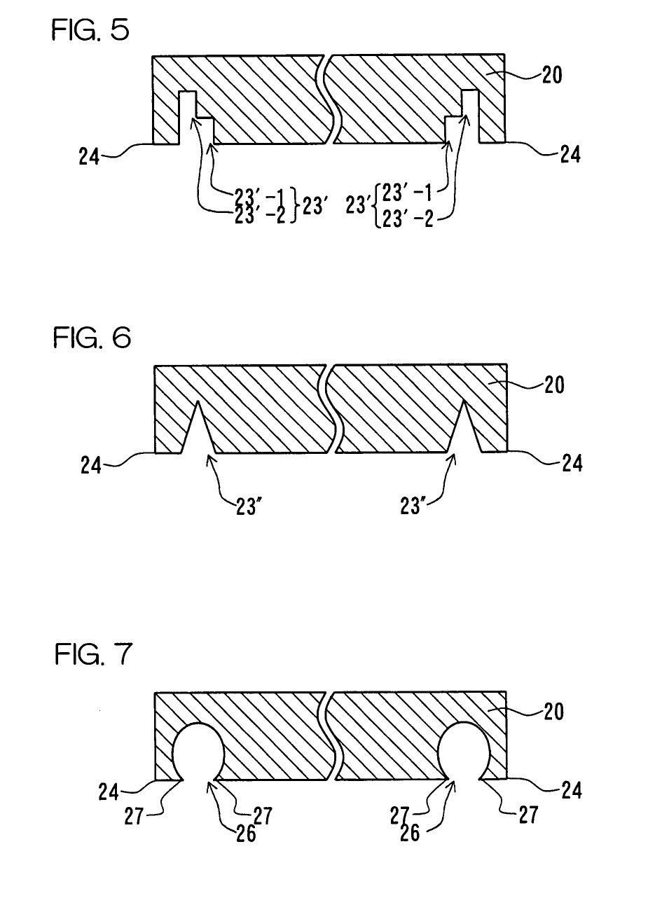

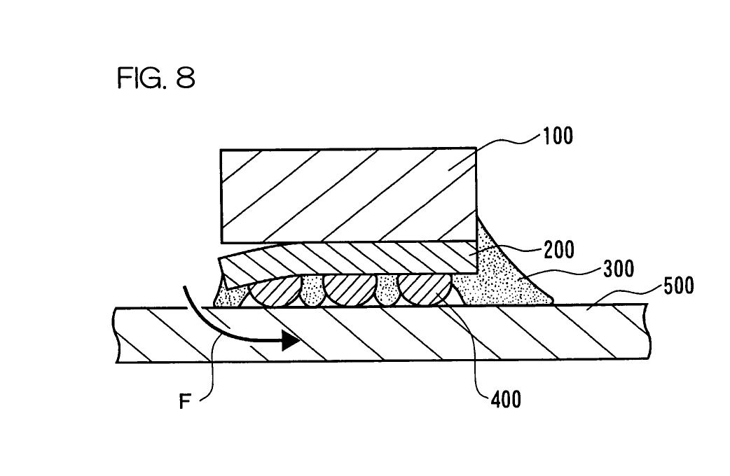

Without limiting to the center of the first groove 23′-1, the second groove 23′-2 may be formed close to the outer peripheral edge 24 side as shown in FIG. 5.

As shown in FIG. 6, in the resin layer 20, tapered grooves 23″ which are narrowed gradually along the depth direction may be formed. By thus tapering the grooves 23″, the underfill material can be smoothly filled, so that the mixing of air can be easily prevented.

When it is demanded to increase the adhesion between the resin layer 20 and the underfill material, as shown in FIG. 7, grooves 26 may be formed in the resin layer 20 by using isotropic etching or the like, whereby hollow portions wider than the openings of the grooves 26 may be provided, and eaves-like projecting pieces 27 may be provided at the openings of the grooves 26.

Embodiments of the present invention are described in detail above, and these are only specific examples used for making the technical contents of the present invention clear, and the present invention should not be limited to these specific examples, and the spirit and scope of the present invention are limited only by the accompanying claims.

The present application corresponds to Japanese Patent Application No. 2006-139622 filed on May 18, 2006 with the Japanese Patent Office, whole disclosure of which is incorporated herein by reference.

What is claimed is:

1. A semiconductor device comprising a semiconductor chip provided with a plurality of electrodes on one surface thereof in a thickness direction, and a resin layer provided so as to overlap the one surface of the semiconductor chip, a surface of the resin layer used as a mounting surface, the semiconductor device mounted on the mounting substrate with an underfill material filled between the mounting surface and the mounting substrate, wherein
in the mounting surface, a groove which divides the mounting surface into a plurality of surfaces is provided.

2. The semiconductor device according to claim 1, wherein
in the resin layer, a plurality of metal posts to which solder terminals are respectively connected are provided, and
the groove is provided along an outer edge of the resin layer between the outer edge and the posts.

3. The semiconductor device according to claim 2, wherein
the mounting surface is in a rectangular shape, and
the grooves are provided along four outer peripheral edges of the mounting surface, respectively.

4. The semiconductor device according to claim 2, wherein
the mounting surface is in a rectangular shape, and
the grooves are provided along two outer peripheral edges adjacent to each other among the four outer peripheral edges of the mounting surface.

5. The semiconductor device according to claim 1, wherein
the groove is inclined at a predetermined angle with respect to the mounting surface.

6. The semiconductor device according claim 1, wherein
the groove has a step formed by a portion grooved relatively shallowly and a portion grooved relatively deeply.
